(19) United States
(12) Patent Application Publication
(10) Pub. No.: US 2003/0116824 A1
(43) Pub. Date: Jun. 26, 2003

(54) Bipolar transistor

(75) Inventor: Tae Won Lee, Seoul (KR)

Correspondence Address: LOWE HAUPTMAN GOPSTEIN GILMAN & BERNER, LLP, Suite 310, 1700 Diagonal Road, Alexandria, VA, 22314, US

(73) Assignee: Samsung Electro-Mechanics Co., Ltd.

(21) Appl. No.: 10/126,621

(22) Filed: Apr. 22, 2002

(30) Foreign Application Priority Data
Dec. 21, 2001 (KR) 2001-82659

(51) Int. Cl. H01L 27/082

(52) U.S. Cl. 257/592

(57) ABSTRACT

A bipolar transistor is provided. The bipolar transistor includes a collector region including a semiconductor substrate doped with a first conductive dopant, an intrinsic base region low-concentration doped with a second conductive dopant on the semiconductor substrate, the second conductive dopant being contrary to the first conductive dopant, an emitter region doped with the first conductive dopant on a first portion of the upper surface of the low-concentration intrinsic base region, an extrinsic base region high-concentration doped with the second conductive dopant on a second portion of the upper surface of the low-concentration intrinsic base region and having a depth between 60% and 100% of the depth of the emitter region, the second portion spaced from the first portion by a designated interval, a collector electrode formed on the lower surface of the semiconductor substrate, an emitter electrode formed on the upper surface of the emitter region, and a base electrode formed on the upper surface of the high-concentration extrinsic base region.

### BACKGROUND OF THE INVENTION

1. Field of the Invention

The present invention relates to a bipolar transistor, more particularly to a bipolar transistor in which the density of emitter current on a base is reduced, thereby heightening electrostatic discharge (ESD) withstand voltage.

2. Description of the Related Art

As well known to those skilled in the art, a bipolar transistor is generally a semiconductor device having two PN junctions between a base and a collector and between a base and an emitter on a silicon substrate, so as to carry out switching and amplifying functions.

The aforementioned two PN junctions are called an emitter-base junction and a collector-base junction, respectively. Modulation of the current flow at a PN junction by the change of bias at an adjacent junction is referred to as a bipolar transistor action.

During the bipolar transistor action, when the reverse bias is applied to the emitter-base junction, the increase of the reverse bias voltage may break the device or melt its material. This voltage causing the breakdown of the device is called an electrostatic discharge (ESD) withstand voltage. The ESD withstand voltage serves as an index for measuring the stability of the semiconductor device.

In order to heighten the ESD withstand voltage, some approaches employ a base region comprising an intrinsic base region of low-concentration and an extrinsic base region of high-concentration and thin junction depth, which is formed on the low-concentration intrinsic base region. With the aforementioned configuration, the low-concentration base region having a junction with the emitter increases breakdown voltage, i.e., a factor for determining the withstand voltage, and the high-concentration base region decreases the base resistance and achieves high-speed performance.

FIG. 1 is a partial cross-sectional view of a conventional bipolar transistor. As shown in FIG. 1, the conventional bipolar transistor in NPN-type includes a collector region, a base region and an emitter region 4. The collector region includes a high-concentration N-type silicon substrate 1 and a low-concentration N-type epitaxial layer 2 on the silicon substrate 1. The base region includes an intrinsic base region 3, which is low-concentration doped with P-type dopant on the N-type epitaxial layer 2, and an extrinsic base region 5, which is high-concentration doped with P-type dopant on the low-concentration intrinsic base region 3. The emitter region 4 is doped with N-type dopant on the low-concentration intrinsic base region 3.

An oxide layer 8 is formed on the uppermost surface and partially opened to form an emitter electrode 6 and a base electrode 7 on the emitter region 4 and the high-concentration extrinsic base region 5, respectively, with poly silicon or metal. Although not shown in FIG. 1, a collector electrode is additionally formed on the lower surface of the N-type silicon substrate 1.

As described in the conventional NPN-type bipolar transistor of FIG. 1, the high-concentration extrinsic base region 5 has a thin junction depth so as to achieve high-frequency performance. Due to the thin junction depth of the high-concentration extrinsic base region 5, its both edges, which lie adjacent to the emitter region 4, have much thinner depths than that of its center. Thereby, as represented by arrows, the emitter current is concentrated on the edges of the high-concentration extrinsic base region 5 under the reverse bias condition between the emitter and the base. Such a current density may degrade the transistor, and in more extreme cases melt or break the device.

As also shown in FIG. 1, the low-concentration intrinsic base region 3 is partially exposed to the base electrode 7, thereby increasing the density of the emitter current and thus breaking the device.

As described above, in the conventional bipolar transistor, the thin edges of the high-concentration extrinsic base region and the contacting area between the base electrode on the high-concentration extrinsic base region and the low-concentration intrinsic base region reduce the ESD withstand voltage of the device.

### SUMMARY OF THE INVENTION

Therefore, the present invention has been made in view of the above problems, and it is an object of the present invention to provide a bipolar transistor comprising a high-concentration base region, which retains high-frequency characteristic and at the same time has a predetermined junction depth suitable for current density dispersion, and a base electrode being capable of heightening the electrostatic discharge (ESD) level.

In accordance with one aspect of the present invention, the above and other objects can be accomplished by the provision of a bipolar transistor comprising a collector region including a semiconductor substrate doped with a first conductive dopant, an intrinsic base region low-concentration doped with a second conductive dopant on the semiconductor substrate, the second conductive dopant being contrary to the first conductive dopant, an emitter region doped with the first conductive dopant on a first portion of the upper surface of the low-concentration intrinsic base region, an extrinsic base region high-concentration doped with the second conductive dopant on a second portion of the upper surface of the low-concentration intrinsic base region and having a depth between 60% and 100% of the depth of the emitter region, the second portion spaced from the first portion by a designated interval, a collector electrode formed on the lower surface of the semiconductor substrate, an emitter electrode formed on the upper surface of the emitter region, and a base electrode formed on the upper surface of the high-concentration extrinsic base region.

Preferably, the base electrode may comprise at least the upper surface of the high-concentration extrinsic base region.

Further, preferably, the high-concentration extrinsic base region is formed on at least both sides of the emitter region and horizontally spaced from the emitter region by the same interval so as to uniformly distribute the current flowing from the emitter region over the high-concentration extrinsic base region.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view of a conventional bipolar transistor;

FIG. 2 is a cross-sectional view of a bipolar transistor in accordance with one aspect of the present invention; and

FIG. 3 is a graph showing the change of the electrostatic discharge (ESD) withstand voltage in relation to the change of the junction depth of the high-concentration extrinsic base region.

### DESCRIPTION OF THE PREFERRED EMBODIMENTS

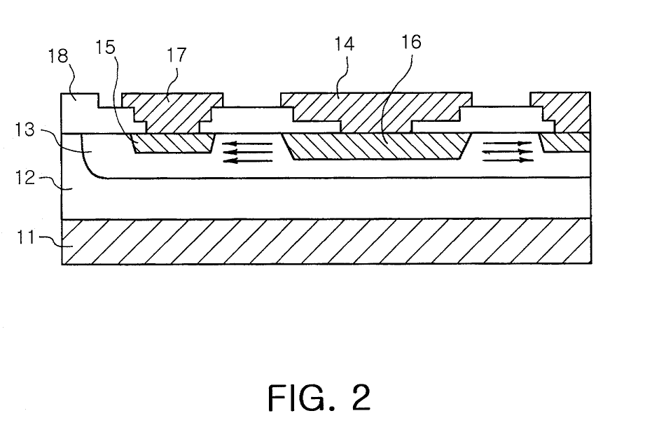

FIG. 2 is a cross-sectional view of a bipolar transistor in accordance with one aspect of the present invention. Referring to FIG. 2, the bipolar transistor of NPN type of the present invention is manufactured by using N-type dopant as a first conductive dopant and P-type dopant as a second conductive dopant.

As shown in FIG. 2, the NPN-type bipolar transistor includes a collector region, a base region, and an emitter region 16.

The collector region includes a high-concentration N-type silicon substrate 11 and a low-concentration N-type epitaxial layer 12 on the silicon substrate 11. The base region includes an intrinsic base region 13, which is low-concentration doped with P-type dopant on the N-type epitaxial layer 12, and an extrinsic base region 15, which is high-concentration doped with P-type dopant on the low-concentration intrinsic base region 13. The emitter region 16 is doped with N-type dopant on the low-concentration intrinsic base region 13.

An oxide layer 18 is formed on the upper surface of the N-type epitaxial layer 12 with a material such as SiO₂ and partially opened to form an emitter 14 and a base electrode 17 on the emitter region 16 and the high-concentration extrinsic base region 15, respectively, with poly silicon or metal. Although not shown in FIG. 2, a collector electrode is additionally formed on the lower surface of the N-type silicon substrate 11.

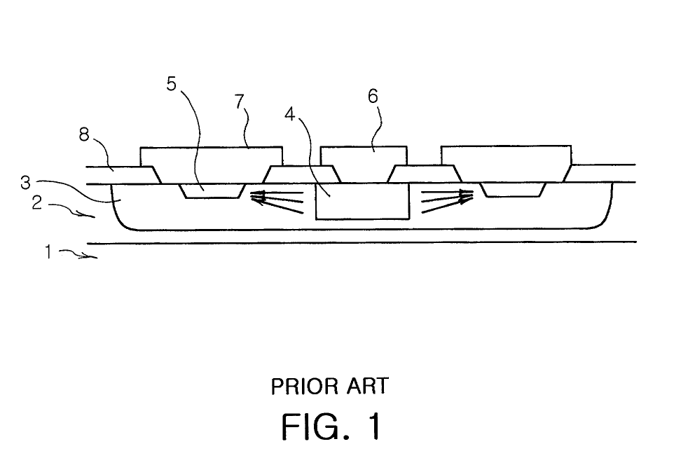

In the NPN-type bipolar transistor of this aspect of the present invention, the high-concentration extrinsic base region 15 is configured such that the depth of the emitter region 16 to the depth of the high-concentration extrinsic base region 15 is in the ratio of 1:0.9. Therefore, if reverse bias is applied to the emitter-base junction, differing from the conventional case in FIG. 1, the current flowing from the emitter 14 is uniformly distributed over a comparatively large area of the high-concentration extrinsic base region 15. This current distribution can increase the ESD withstand voltage.

In order not to join the base electrode 17 on the high-concentration extrinsic base region 15 with the low-concentration intrinsic base region 13, the base electrode 17 is formed above the high-concentration extrinsic base region 15. Therefore, the ESD withstand voltage may be heightened by blocking the flow of the emitter current into the base electrode 17 joined with the low-concentration intrinsic base region 13.

Additionally, this aspect of the present invention may employ an improvement in structure, in which a plurality of the high-concentration extrinsic base regions 15 are spaced from the emitter region 16 by a uniform interval. Thereby, the concentration of the current density on a specific area of the high-concentration extrinsic base region 15 is prevented and the current is uniformly distributed, consequently improving the ESC withstand voltage.

As described above, the present invention may effectively and uniformly distribute the emitter current to the high-concentration extrinsic base region 15 by increasing the depth of the high-concentration extrinsic base region 15 and enlarging its edges joined with the emitter region 14. Moreover, the present invention prevents the current from directly flowing into the base electrode 17 via the low-concentration intrinsic base region 13 by forming the base electrode 17 above the high-concentration extrinsic base region 15, but not joining the base electrode 17 with the low-concentration intrinsic base region 13. This alignment of the base electrode 17 of the present invention also improves the ESD withstand voltage.

However, the increase of the junction depth of the high-concentration extrinsic base region is limited by the decrease of the breakdown voltage of the base-collector junction. That is, the increase of the junction depth of the high-concentration extrinsic base region enlarges its edges being capable of distributing the current from the emitter, but shrinks the low-concentration intrinsic base region for forming a junction with the collector region. Thereby, the breakdown voltage of the base-collector junction may be rapidly reduced.

Accordingly, the inventors of the present invention carried out an experiment. Through this experiment, the inventors studied the effect of heightening the ESD withstand voltage and the effect of decreasing the breakdown voltage of the base-collector junction by increasing the junction depth of the high-concentration extrinsic base region. This experimental test is to find a range of the junction depth of the high-concentration extrinsic base region so as to increase the ESD withstand voltage.

### EXAMPLE

Five N-type silicon substrates, which were doped with antimony (Sb) under the same conditions, were prepared. An intrinsic base region was formed by low-concentration doping the if silicon substrate with P-type dopant, i.e., boron (B) and an emitter region was formed at a depth of 1.5 μm by doping a portion of the low-concentration intrinsic base region with antimony (Sb). Thereby, five samples were manufactured.

All the high-concentration extrinsic base regions of the 5 samples were configured to be spaced from the emitter region by the same interval. However, the high-concentration extrinsic base region of each sample had a specific junction depth differing from that of the other samples. That is, in order to vary the junction depth of the high-concentration extrinsic base region of each sample formed with the same P-type dopant in an amount of 2×10¹⁵ atoms/cm³, the ion implantation energies were variously applied in an amount of 50 KeV, 100 KeV, 150 KeV, 180 KeV, and 200 KeV. The implanted depths by various ion implantation energies were 1608 Å, 2994 Å, 4205 Å, 4872 Å, and 5297 Å, respectively. The final depths of the high-concentration extrinsic base region obtained by diffusing the samples at 1000° C. for 25 minutes in a nitrogen atmosphere were 0.82 μm, 1.05 μm, 1.39 μm, 1.53 μm, and 1.61 μm.

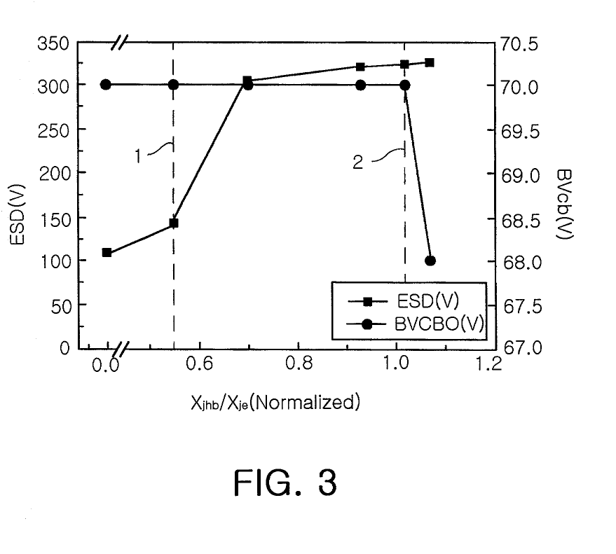

When reverse bias was applied to the emitter-base junctions of 5 samples, the ESD withstand voltages of the five samples were measured. The results are shown in table 1 and the graph of FIG. 3. FIG. 3 is a graph showing the change of the electrostatic discharge (ESD) withstand voltage in relation to the change of the junction depth of the high-concentration extrinsic base region.

TABLE 1

| | high-concentration | | | | | ESD |
|---|---|---|---|---|---|---|
| | extrinsic base region | | | | | withst |
| | | ion | | | | and |
| | dose | implantation | Rp | Xjhb | Xjhb/ | voltage |
| | (atoms/cm³) | energy (Kev) | (Å) | (μm) | Xje | (V) |
| sample | 2 × 10¹⁵ | 50 | 1608 | 0.82 | 0.55 | 143 |
| 1 | | | | | | |
| sample | 2 × 10¹⁵ | 100 | 2994 | 1.05 | 0.70 | 305 |
| 2 | | | | | | |
| sample | 2 × 10¹⁵ | 150 | 4205 | 1.39 | 0.93 | 320 |
| 3 | | | | | | |
| sample | 2 × 10¹⁵ | 180 | 4872 | 1.53 | 1.02 | 323 |
| 4 | | | | | | |
| sample | 2 × 10¹⁵ | 200 | 5297 | 1.61 | 1.07 | 325 |
| 5 | | | | | | |

Herein, Rp is an implanted depth of the P-type dopant at the corresponding ion implantation energy. Xjhb is a depth of the high-concentration extrinsic base region formed by the diffusion process. Xje is a depth of the emitter region. Further, BVCBO is a breakdown voltage of the base-collector junction.

As shown in Table 1, the ESD withstand voltage of sample 1 was 143V. However, the ESD withstand voltage rapidly increased, as a value of Xjhb/Xje was greater than 0.60. The more the depth of the high-concentration extrinsic base region increases, the more the ESD withstand voltage is improved. However, as shown in an area corresponding to sample 5 in FIG. 3, when the depth of the high-concentration extrinsic base region was more than the depth of the emitter region, the breakdown voltage of the base-collector junction rapidly dropped. This may cause other problems on the base-collector junction. Therefore, the depth of the high-concentration extrinsic base region is preferably 60% to 100% of the depth of the emitter region (that is, at the range between 1 and 2 in FIG. 3).

As apparent from the above description, the present invention provides a bipolar transistor, in which its high-concentration extrinsic base region is configured to have a predetermined depth considering the depth of the emitter region, thereby uniformly distributing the emitter current density and heightening the ESD withstand voltage. Further, the base electrode of the present invention is formed on the upper surface of the high-concentration extrinsic base region but not joined with the low-concentration intrinsic base region, thereby preventing the current from directly flowing into the base electrode via the low-concentration intrinsic base region.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is

1. A bipolar transistor comprising:
a collector region including a semiconductor substrate doped with a first conductive dopant;
an intrinsic base region low-concentration doped with a second conductive dopant on said semiconductor substrate, said second conductive dopant being contrary to said first conductive dopant;
an emitter region doped with said first conductive dopant on a first portion of the upper surface of said intrinsic base region;
an extrinsic base region high-concentration doped with said second conductive dopant on a second portion of the upper surface of said low-concentration intrinsic base region and having a depth between 60% and 100% of the depth of said emitter region, said second portion spaced from said first portion by a designated interval;
a collector electrode formed on the lower surface of said semiconductor substrate;
an emitter electrode formed on the upper surface of said emitter region; and
a base electrode formed on the upper surface of said high-concentration y extrinsic base region.

2. The bipolar transistor as set forth in claim 1, wherein said base electrode is positioned on the region including at least the upper surface of said high-concentration extrinsic base region.

3. The bipolar transistor as set forth in claim 1, wherein said high-concentration extrinsic base region is formed on at least both sides of said emitter region and horizontally spaced from said emitter region by the same interval so as to uniformly distribute the current flowing from said emitter region over said high-concentration extrinsic base region.
